(19) United States
(12) Patent Application Publication
(10) Pub. No.: US 2012/0127662 A1
(43) Pub. Date: May 24, 2012

(54) ELECTRONIC APPARATUS AND KEYBOARD SUPPORTING MODULE THEREOF

(75) Inventors: Kuang-Chung SUN, TAIPEI CITY (TW); Wei-Yi LIN, TAIPEI CITY (TW); Li-Ting WANG, TAIPEI CITY (TW); Ting-Chiang HUANG, TAIPEI CITY (TW); Feng-Ku WANG, TAIPEI CITY (TW)

(73) Assignee: INVENTEC CORPORATION, TAIPEI CITY (TW)

(21) Appl. No.: 12/981,522

(22) Filed: Dec. 30, 2010

(30) Foreign Application Priority Data
Nov. 19, 2010 (TW) 099140017

(51) Int. Cl. H05K 7/20; H05K 7/00

(52) U.S. Cl. 361/690; 361/679.01; 361/688; 361/707

(57) ABSTRACT

An electronic apparatus and a keyboard supporting module thereof are provided. The electronic apparatus includes a heat source, the keyboard supporting module and a push-button key module. The keyboard supporting module includes a keyboard supporting structure and an insulator. The keyboard supporting structure is thermally connected to the heat source. Particularly, the keyboard supporting structure supports the push-button key module with the insulator.

### RELATED APPLICATIONS

This application claims priority to Taiwan Application Serial Number 099140017, filed Nov. 19, 2010, which is herein incorporated by reference.

### BACKGROUND

1. Field of Invention

The present invention relates to an electronic apparatus and a keyboard supporting module thereof.

2. Description of Related Art

For a conventional portable computer (for example, a notebook computer or a laptop computer), typically its keyboard module is directly installed on the main body, that is, the keyboard module is directly installed in a housing slot of the main body. Therefore, the heat generated inside the main body in operation is delivered to the whole main body. Since the keyboard module is directly installed on the top of the main body, the keyboard module directly received the heat dissipated from the main body.

Although the main body typically has a heat dissipation system therein, the heat dissipation system is mainly designed to dissipate heat from a central processing unit (CPU) and a whole heat source. With respect to the problem of dissipating heat to an external surface of the main body, the heat dissipation system inside the main body has limited efficacy, which only has the natural heat dissipation from the external surface of the main body contacting air.

For instance, the currently existing notebook computers mostly use a keyboard support as a heat sink. In consideration of providing the keyboard module with a good support in mechanism, in the current design, the keyboard support and the keyboard module are mostly assembled without clearance. However, in this manner, the keyboard support (usually, an aluminum panel) directly contacts a metal part at the bottom of the keyboard module, and thus the heat may be directly transmitted to the metal part at the bottom of the keyboard module.

Although the plastic structure of a keycap itself is a good insulator, yet, when the CPU load is high, a surface temperature of the keyboard module will be excessively high (higher than 40° C.), and the situation is more apparent in a fanless machine, thus causing user uncomfortableness. Furthermore, it is known from experience that, when the temperature of the keyboard module is higher than 65° C., the normal operation of the keyboard module will be greatly affected, which further causes keyboard malfunction, that is, pressing the keyboard will deliver no signals to the main body.

### SUMMARY

To solve the problems of the conventional skill, the present invention is directed to provide an electronic apparatus and a keyboard supporting module thereof, thereby solving the problem that a surface temperature of the keyboard rises too fast and thus causes user uncomfortableness in operation; or the problem that the temperature of the keyboard is excessively high and thus causes invalid keyboard input function.

To achieve the above objectives, the present invention provides a keyboard supporting module mainly for supporting the keyboard module. The keyboard supporting module of the present invention includes a keyboard supporting structure and an insulator. The insulator is disposed between the keyboard supporting structure and the keyboard module. In other words, the keyboard supporting module of the present invention supports the keyboard module with the insulator.

According to an embodiment of the present invention, an air gap may be formed in the insulator to decrease the thermal conductivity of the insulator.

According to another embodiment of the present invention, the insulator may also include a hermetic air cavity to increase the thermal conductivity.

Of course, according to yet another embodiment of the present invention, the insulator may be an air cushion as a whole.

Additionally, the present invention provides a keyboard supporting module. The keyboard supporting module of the present invention includes a keyboard supporting structure and a mesh insulator. The mesh insulator is disposed between the keyboard supporting structure and the keyboard module. In other words, the keyboard supporting module supports the keyboard module with the mesh insulator.

According to an embodiment of the present invention, the keyboard module includes a plurality of push-button key modules, and the mesh insulator collaboratively supports the rim of each push-button key module.

According to another embodiment of the present invention, the mesh insulator may have a plurality of hollow portions, and each hollow portion corresponds to a push-button key module.

According to yet another embodiment of the present invention, the contour of each hollow portion may be geometrically consistent with the contour of the corresponding push-button key module. In other words, under the prerequisite of sufficiently supporting each push-button key module, the larger the area of the hollow portion is, the smaller overall thermal conductivity the mesh insulator has.

Of course, in a practical application, the number of the hollow portions of mesh insulator is not required to be consistent with the number of the push-button key modules, as long as the push-button key modules are effectively supported and will not fall into the hollow portions of the mesh insulator.

The present invention further provides an electronic apparatus. The electronic apparatus of the present invention includes a heat source, a keyboard supporting structure, an insulator and a keyboard module. The keyboard supporting structure is thermally connected to the heat source. The insulator is disposed on the keyboard supporting structure. The keyboard supporting structure supports the keyboard module with the insulator: By disposing the insulator between the keyboard supporting structure and the keyboard module, the problem that the surface temperature of the keyboard rises too fast and thus causes user uncomfortableness in operation, and the problem that the temperature of the keyboard is excessively high and thus causes invalid keyboard input function are solved.

These and other objectives, features, and advantages of the present invention will become better understood with detailed description made to the following preferred embodiments and appended drawings.

### BRIEF DESCRIPTION OF THE DRAWINGS

The following objectives, features, and advantages of the present invention can be more fully understood, with reference made to the accompanying drawings as follows:

FIG. 1 is a three-dimensional view of an electronic apparatus according to an embodiment of the present invention;

FIG. 2 is a schematic sectional view of an electronic apparatus viewed along Line A-A of FIG. 1;

FIG. 3A is a schematic sectional view of a keyboard supporting module according to an embodiment of the present invention;

FIG. 3B is an exploded view of a keyboard module and a mesh insulator of FIG. 3A;

FIG. 4 is a schematic sectional view of a specific embodiment of a is keyboard supporting module of FIG. 3A;

FIG. 5 is a schematic sectional view of another specific embodiment of a keyboard supporting module of FIG. 3A;

FIG. 6 is a schematic view of an equivalent thermal resistance R₁ of a keyboard supporting module without an insulator adopted between the heat source and the keyboard module; and

FIG. 7 is a schematic view of an equivalent thermal resistance R₄ of the keyboard supporting module of the present invention adopted between the heat source and the keyboard module.

### DETAILED DESCRIPTION

The present invention provides an electronic apparatus and a keyboard supporting module thereof. More particularly, the present invention is mainly directed to the improvement on the structure of the conventional keyboard supporting module, so as to effectively solve the problem that a surface temperature of the keyboard rises too fast and thus causes user uncomfortableness in operation, or the problem of the temperature of the keyboard is excessively high and thus causes input function failure. Hereinafter, the features, spirits, advantages and convenience in implementation of the present invention are sufficiently explained with reference to the specific embodiments of the present invention.

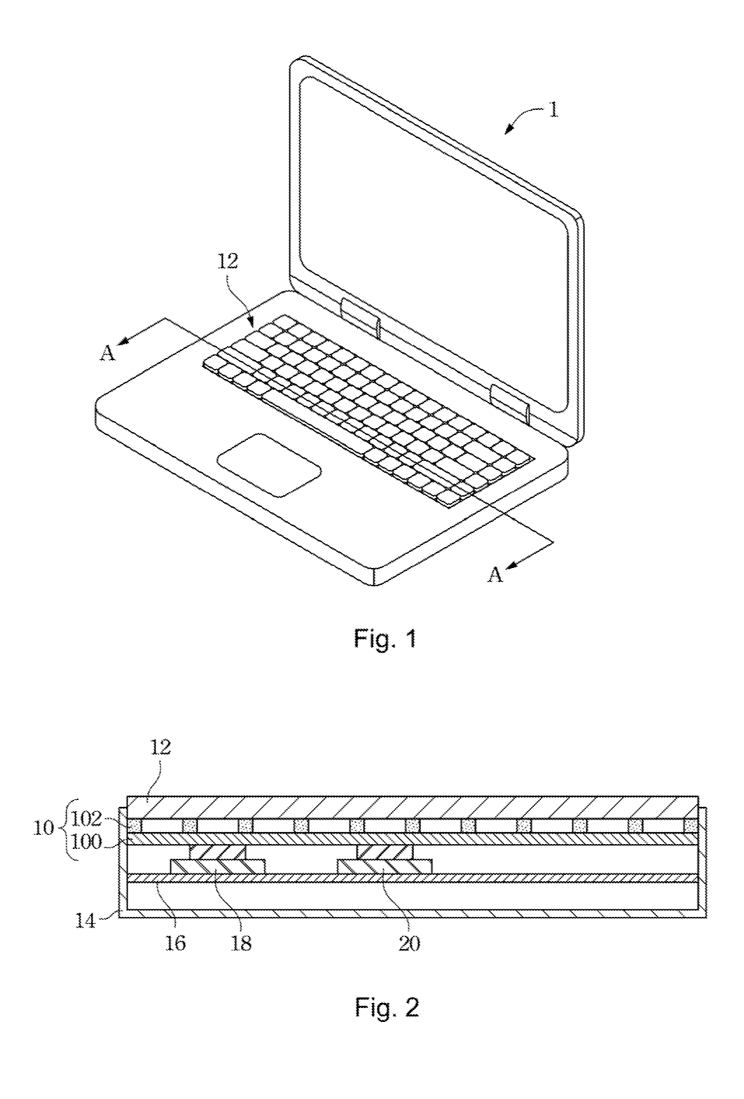

Referring to FIG. 1, FIG. 1 is a three-dimensional view of an electronic apparatus 1 according to an embodiment of the present invention.

As shown in FIG. 1, the electronic apparatus 1 of the present invention may be, but not limited to, a portable computer having a keyboard module 12 (for example, a notebook computer or a laptop computer). In other words, the electronic apparatus 1 of the present invention may be any electronic product having the keyboard module 12, as long as the keyboard module 12 has a heat source disposed therebelow, and the concept of the present invention can be used to solve the problem of the keyboard module 12 having excessive high temperature.

Referring to FIG. 2, FIG. 2 is a schematic sectional view of an electronic apparatus 1 viewed along Line A-A of FIG. 1. As shown in FIG. 2, the electronic apparatus 1 of the present invention may include a keyboard supporting module 10, a keyboard module 12, a shell 14, a main board 16, a north bridge chip 18 and a CPU chip 20. Hereinafter, the structural configurations of all components inside the shell 14 of the electronic apparatus 1 of the present invention are illustrated in details.

As shown in FIG. 2, the main board 16 is disposed in the shell 14, and the CPU chip 20 is detachably disposed on the main board 16, and the north bridge chip 18 is disposed (usually in a welding manner) on the main board 16. Of course, in practical application, the electronic apparatus 1 of the present invention is not limited to the one including a CPU chip 20 and a north bridge chip 18, and in the present invention, only the CPU chip 20 and the north bridge is chip 18 are taken as the main heat sources of the electronic apparatus 1 for the simplicity of illustration. In the operation course of the electronic apparatus 1 of the present invention after being powered on, the CPU chip 20 and the north bridge chip 18 often generate massive heat.

As also shown in FIG. 2, the keyboard supporting module 10 of the present invention includes a keyboard supporting structure 100 and a mesh insulator 102. The keyboard supporting structure 100 is disposed in the shell 14 and is thermally connected to the CPU chip 20 and the north bridge chip 18 on the main board 16. In other words, the keyboard supporting structure 100 may function as a heat sink for the electronic components such as the CPU chip 20 and the north bridge chip 18 on the main board 16. Therefore, typically, a material forming the keyboard supporting structure 100 may be, but not limited to, aluminum.

Furthermore, the mesh insulator 102 may be disposed between the keyboard supporting structure 100 and the keyboard module 12. In the course of fabrication, the mesh insulator 102 of the present invention may be just placed between the keyboard supporting structure 100 and the keyboard module 12. In order to prevent the undesired displacement of the mesh insulator 102, the mesh insulator 102 of the present invention may be disposed on the keyboard supporting module 10 through the existing skills such as adhesive bonding and hot melting, such that the keyboard module 12 is detachably supported by the mesh insulator 102. On the contrary, the mesh insulator 102 of the present invention may also be disposed below the keyboard module 12 through the existing skills such as adhesive bonding and hot melting, such that the keyboard supporting structure 100 is detachably supported below the mesh insulator 102. Of course, the mesh insulator 102 of the present invention may also be combined with both the keyboard supporting structure 100 and the keyboard module 12 through the existing skills such as adhesive bonding and hot melting, so as to ensure that the mesh insulator 102 does not have any unexpected displacement.

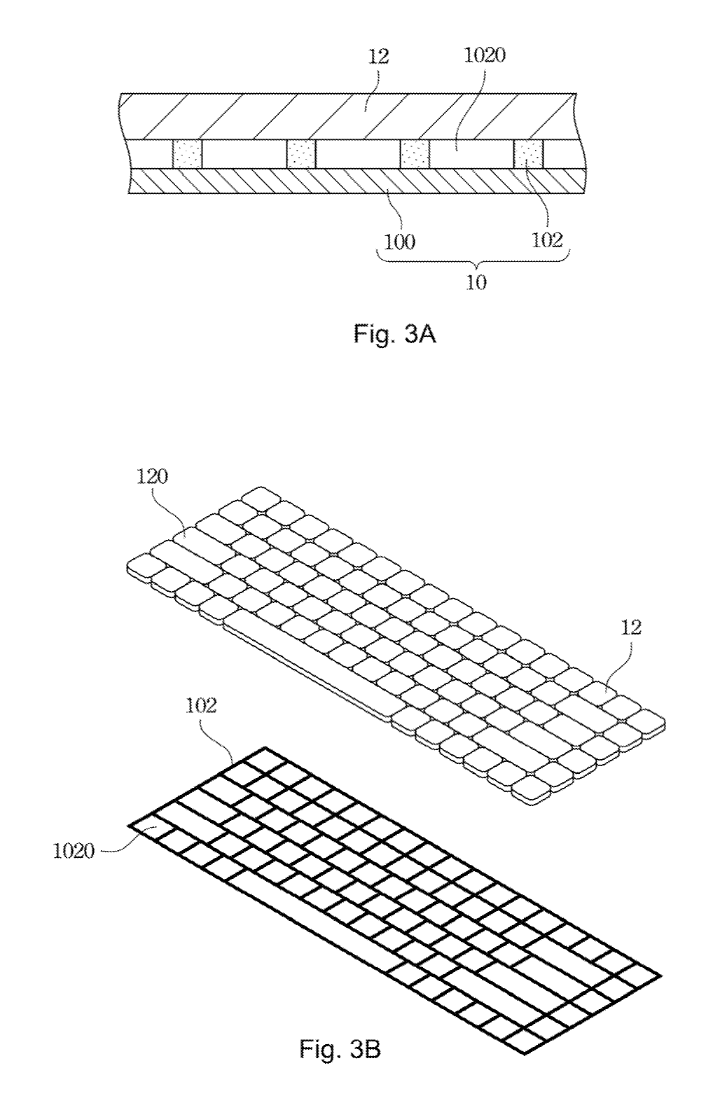

Referring to FIG. 3A and FIG. 3B, FIG. 3A is a schematic sectional view of a keyboard supporting module 10 according to an embodiment of the present invention, and FIG. 3B is an exploded view of the keyboard module 12 and the mesh insulator 102 of FIG. 3A. As shown in FIG. 3A and FIG. 3B, the keyboard module 12 includes a plurality of push-button key modules 120, and the mesh insulator 102 may collaboratively support the rim of each push-button key module 120.

Therefore, in an embodiment, as shown in FIG. 3B, the mesh insulator 102 of the present invention may include a plurality of hollow portions 1020 each of which corresponds to a push-button key module 120, whereby the mesh insulator 102 may support the rim of each push-button key module 120 with the portions except the hollow portions 1020 of the mesh insulator 102. Of course, the number of the hollow portions 1020 of the mesh insulator 102 of the present invention is not necessarily consistent with the number of the push-button key modules 120, as long as the function of effectively supporting each push-button key module 120 can be achieved.

In a specific embodiment, as shown in FIG. 38, the contour of each hollow portion 1020 of the mesh insulator 102 of the present invention may be geometrically consistent with the contour of the corresponding push-button key module 120. Also, under the prerequisite of effectively providing the function of supporting each push-button key module 120, the larger area the hollow portion 1020 is, the less the heat conduction path is, thereby effectively solving the problem that the surface temperature of the keyboard rises too fast.

In a specific embodiment, a material of the mesh insulator 102 of the present invention may be, but not limited to, plastic. In other words, the mesh insulator 102 may be made of any material having the thermal conductivity smaller than 200 W/m° C. to achieve the purpose of the present invention.

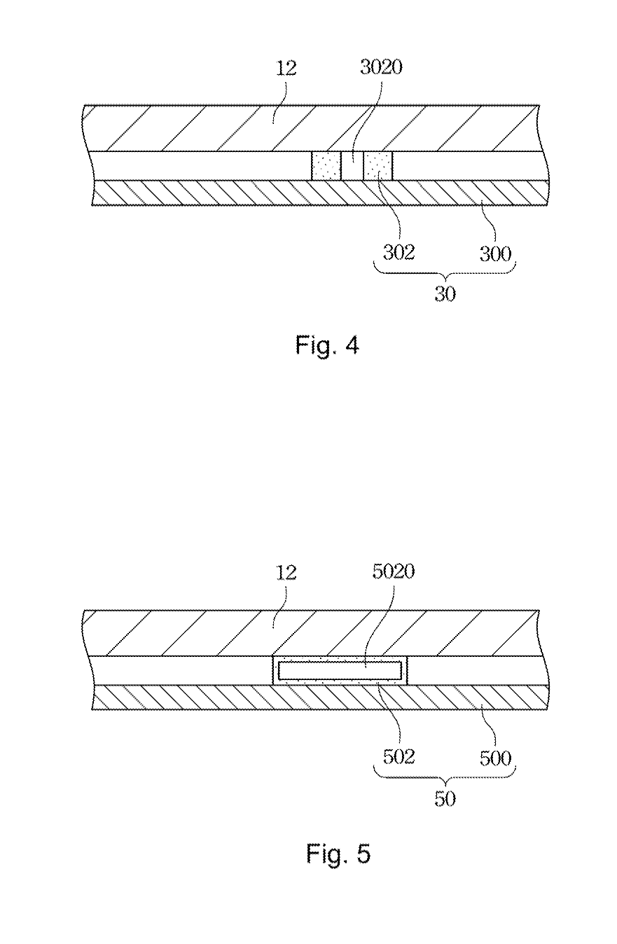

Referring to FIG. 4, FIG. 4 is a schematic sectional view of a specific embodiment of a keyboard supporting module 10 of FIG. 3A. As shown in FIG. 4, the keyboard supporting module 30 of the present invention may include a keyboard supporting structure 300 and an insulator 302. In other words, the insulator 302 may be disposed in various patterns on the keyboard supporting structure 300, and each insulator 302 may serve as a supporting point, as long as the function of supporting each push-button key module 120 of the keyboard module 12 without contacting the keyboard supporting structure 300 can be effectively achieved. The arrangements among the insulator 302, the keyboard supporting structure 300 and the keyboard module 12 are described as above, and the details thereof will not be repeated herein.

As shown in FIG. 4, each insulator 302 of the present invention may include an air gap 3020. In a specific embodiment, each air gap 3020 may connect with the keyboard supporting structure 300 and the keyboard module 12. In other words, the form of the air gap 3020 of this specific embodiment can reduce the contact area between the insulator 302 and the keyboard supporting structure 300 and that between the insulator 302 and the keyboard module 12 respectively. Of course, the form of the air gap 3020 is not limited to the above embodiment, and may also connect with the keyboard supporting structure 300 only or with the keyboard module 12 only. In summary, as long as the air gap is in an open form, the contact area between the insulator 302 and the keyboard supporting structure 300 or that between the insulator 302 and the keyboard module 12 can be reduced, thereby reducing the paths of heat conduction.

Referring to FIG. 5, FIG. 5 is a schematic sectional view of another specific example of a keyboard supporting module 50 of FIG. 3A. As shown in FIG. 5, the keyboard supporting module 50 of the present invention may also include a keyboard supporting structure 500 and an insulator. The insulator may also be disposed in various patterns on the keyboard supporting structure 500, and each insulator may serve as a supporting point, as long as the function of supporting each push-button key module 120 of the keyboard module 12 without contacting the keyboard supporting structure 500 can be effectively achieved. The arrangements among the insulator, the keyboard supporting structure 500 and the keyboard module 12 are described as above, and the details will not be repeated herein.

As shown in FIG. 5, especially, in a specific embodiment of the present invention, the insulator may be an air cushion 502. An air cavity 5020 in the air cushion 502 may be vacuum or filled with a gas having a low thermal conductivity. In other words, not only the form of the air cushion 502 in this specific embodiment can increase the heat resistance of heat conduction via its air cavity 5020, but also the air cushion 502 itself can effectively support the keyboard module 12 on the keyboard supporting structure 500. Of course, the form of the air cushion 502 is not limited to the above embodiment. In addition to merely including the form of one air cavity 5020, in order to enhance the support for the keyboard module 12, the air cushion 502 may also include the form of a plurality of air cavities. In summary, as long as the form of the hermetic air cavity is adopted, the space inside the air cavity may achieve the purpose of increasing the heat resistance, thereby reducing the difficulty in resolving heat transfer problems.

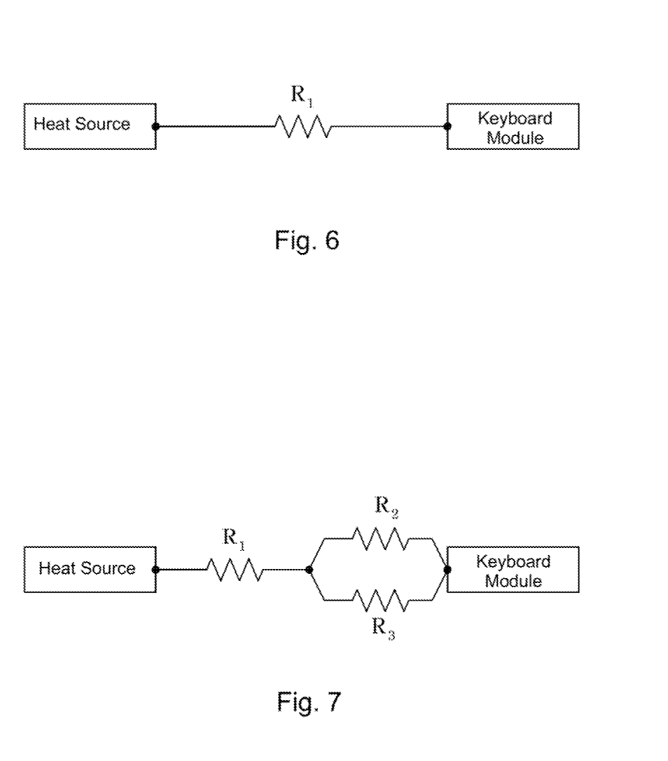

Referring to FIG. 6, FIG. 6 is a schematic view of an equivalent thermal resistance R₁ of a keyboard supporting module without an insulator adopted between the heat source and the keyboard module.

As shown in FIG. 6, in the calculation of the equivalent thermal resistance R₁, for the simplicity of calculation, the following assumptions are made herein.
1. The direction of the heat conduction inside the system is of only one dimension.
2. The contact area A₁ of the keyboard supporting module is 0.01685 m².
3. The material forming the keyboard supporting module is aluminum, and its thermal conductivity K₁ is 202 W/m° C.
4. The thickness ΔX₁ of the keyboard supporting module is 0.0005 m.

Accordingly, the equivalent thermal resistance R₁ of the keyboard supporting module without the insulator as shown in FIG. 6 is calculated as follows:

$${R}_{1} = \frac{Δ {X}_{1}}{{K}_{1} {A}_{1}} = \frac{0.0005}{( 202 \times 0.01685 )} = 0.000147 ( ° C . / W ) \qquad ( 1 )$$

Referring to FIG. 7, FIG. 7 is a schematic view of an equivalent thermal resistance R₄ of a keyboard supporting module of the present invention adopted between the heat source and the keyboard module.

As shown in FIG. 7, likewise, in the calculation of the equivalent thermal resistance R₄, for the simplicity of calculation, the following assumptions are made herein.
1. The direction of the heat conduction inside the system is of only one dimension.
2. The contact area A₂ of the insulator is 0.0117 m².
3. The thermal conductivity K₂ of the insulator is 0.16 W/m° C.
4. The thickness ΔX₂ of the insulator is 0.001 m.
5. The contact area A₃ of the air gap is 0.00515 m².
6. The thermal conductivity K₃ of the air gap is 0.024 W/m° C.
7. The thickness ΔX₃ of the air gap is 0.001 m.

Therefore, the equivalent thermal resistance R₂ of the insulator and the equivalent thermal resistance R₃ of the air gap in FIG. 7 are calculated as follows:

$$\begin{matrix}{R}_{2} = \frac{Δ {X}_{2}}{{K}_{2} {A}_{2}} = \frac{0.001}{0.16 \times 0.00515} = 1.208 ( ° C . / W ) & ( 2 ) \\ {R}_{3} = \frac{Δ {X}_{3}}{{K}_{3} {A}_{3 }} = \frac{0.001}{0.24 \times 0.0117} = 3.571 ( ° C . / W ) & ( 3 )\end{matrix}$$

The equivalent thermal resistance R₂ of the insulator and the equivalent thermal resistance R₃ of the air gap are connected in parallel to obtain the combined heat resistance R_{combined}:

R_{combined}=0.903(° C./W) (4)

Accordingly, the equivalent thermal resistance R₄ of the keyboard supporting module of the present invention of FIG. 7 is calculated as follows:

R₄=R₁+R_{combined}=0.000147+0.903≅0.903(° C./W) (5)

In addition, if only an air gap of 1 mm is kept between the keyboard supporting module and the keyboard module (i.e., no medium is added between the keyboard supporting module and the keyboard module), likewise, in the calculation of the equivalent thermal resistance R₅ of the air gap, for simplicity of calculation, the following assumptions are made herein.
1. The direction of the heat conduction inside the system is of only one dimension.
2. The contact area A₅ of the air gap is 0.01685 m².
3. The thermal conductivity K₅ of the air gap is 0.024 W/m° C.
4. The thickness ΔX₅ of the air gap is 0.001 m.

Accordingly, the equivalent thermal resistance R₅ of the 1 mm air gap kept between the keyboard supporting module and the keyboard module is calculated as follows:

$${R}_{5} = \frac{0.001}{0.024 \times 0.01685} = 2.472 ( ° C . / W ) \qquad ( 6 )$$

Hereinafter, the formula ΔT=R×W is used to compare the differences between the design of the keyboard supporting module without the insulator as shown in FIG. 6, with the design of only keeping 1 mm air gap between the keyboard supporting module and the keyboard module by using the keyboard supporting module of the present invention as shown in FIG. 7, wherein ΔT is a temperature difference (° C.) between the heat source and the keyboard module and W is a heat generation rate (J/s) of the heat source.

It can be seen from the above formula that, when the heat generation rates of the heat sources are the same, a larger heat resistance may obtain a larger ΔT, and in this way, the temperature rising time of the keyboard module is prolonged, thereby reducing the surface temperature of the keyboard module to improve user comfortableness.

However, since a deflection test is conducted on the keyboard module during the mechanism tests, if only 1 mm air gap is kept, the keyboard module will not be able to pass the deflection test.

Therefore, under the prerequisite of sufficiently supporting the keyboard module, a larger contact area of the air gap in the insulator may result in a larger overall equivalent thermal resistance of the insulator.

It can be clearly seen from the above detailed description about the specific embodiments of the present invention that, the electronic apparatus and the keyboard supporting module thereof of the present invention are mainly directed to the improvements of the structure of the conventional keyboard supporting module, which can solve the problems that the surface temperature of the keyboard rises too fast and thus causes user uncomfortableness in operation or the temperature of the keyboard is excessively high and thus causes the input function failure.

In other words, after the insulator is disposed between the existing keyboard supporting structure and keyboard module (no matter whether the insulator includes an air gap or the insulator is an air cushion having an air cavity) in the present invention, the heat is delivered from the keyboard supporting structure (regardless in the form of heat conduction or heat convection) to the keyboard module, the thermal conductivity is greatly reduced (i.e. the heat resistance is increased).

Furthermore, under the prerequisite of sufficiently supporting the push-button key module, the larger area the hollow portion of the mesh insulator of the present invention is, the smaller the thermal conductivity is. Therefore, when a user operates the electronic apparatus of the present invention, the comfort level is effectively improved.

Although the present invention has been described with reference to the above embodiments, these embodiments are not intended to limit the present invention. It will be apparent to those skilled in the art that various modifications and variations can be made without departing from the scope or spirit of the present invention. Therefore, the scope of the present invention shall be defined by the appended claims.

What is claimed is:

1. A keyboard supporting module for supporting a keyboard module, the keyboard supporting module comprising:
a keyboard supporting structure; and
an insulator disposed between the keyboard supporting structure and the keyboard module.

2. The keyboard supporting module of claim 1, wherein the insulator comprises an air gap.

3. The keyboard supporting module of claim 2, wherein the air gap connects with the keyboard supporting structure and the keyboard module.

4. The keyboard supporting module of claim 1, wherein the insulator comprises a hermetic air cavity.

5. The keyboard supporting module of claim 1, wherein the insulator is an air cushion.

6. The keyboard supporting module of claim 1, wherein the insulator is a mesh insulator.

7. The keyboard supporting module of claim 6, wherein the keyboard module comprises a plurality of push-button key modules, and the mesh insulator collaboratively supports the rim of each of the push-button key modules.

8. The keyboard supporting module of claim 7, wherein the mesh insulator has a plurality of hollow portions, and each of the hollow portions corresponds to one of the push-button key modules.

9. The keyboard supporting module of claim 8, wherein the contour of each of the hollow portions is geometrically consistent with the contour of the corresponding push-button key module.

10. An electronic apparatus, comprising:
a heat source;
a keyboard supporting structure thermally connected to the heat source;
an insulator disposed on the keyboard supporting structure; and
a keyboard module supported by the keyboard supporting structure with the insulator.

11. The electronic apparatus of claim 10, wherein the insulator comprises an air gap.

12. The electronic apparatus of claim 11, wherein the air gap connects with the keyboard supporting structure and the keyboard module.

13. The electronic apparatus of claim 10, wherein the insulator comprises a hermetic air cavity.

14. The electronic apparatus of claim 10, wherein the insulator is an air cushion.

15. The electronic apparatus of claim 10, wherein the insulator is a mesh insulator.

16. The electronic apparatus of claim 15, wherein the thermal conductivity of the insulator is smaller than 200 W/m° C.

17. The electronic apparatus of claim 15, wherein the keyboard module comprises a plurality of push-button key modules, and the insulator collaboratively supports the rim of each of the push-button key modules.

18. The electronic apparatus of claim 17, wherein the insulator has a plurality of hollow portions, and each of the hollow portions corresponds to one of the push-button key modules.

19. The electronic apparatus of claim 18, wherein the contour of each of the hollow portions is geometrically consistent with the contour of the corresponding push-button key module.

20. An electronic apparatus, comprising:
a heat source;
a keyboard supporting structure thermally connected to the heat source;
a mesh insulator disposed on the keyboard supporting structure and comprising a plurality of hollow portions; and
a keyboard module comprising a plurality of push-button key modules, wherein the mesh insulator collaboratively supports the rim of each of the push-button key modules;
wherein each of the hollow portions corresponds to one of the push-button key modules, and the contour of each of the hollow portions is geometrically consistent with the contour of the corresponding push-button key module.
